(19) United States
(12) Patent Application Publication
(10) Pub. No.: US 2026/0038615 A1
(43) Pub. Date: Feb. 5, 2026

(54) MEMORY FAULT DIAGNOSIS DEVICE USING BLOOM FILTER, SOC, BLOOM FILTER UPDATE METHOD, AND MEMORY ACCESSIBILITY DETERMINATION METHOD

(71) Applicants: SK hynix Inc., Icheon-si (KR); EWHA UNIVERSITY-INDUSTRY COLLABORATION FOUNDATION, Seoul (KR)

(72) Inventors: Ji Hoon KIM, Seoul (KR); Sun Young PARK, Seoul (KR)

(21) Appl. No.: 18/956,456

(22) Filed: Nov. 22, 2024

(30) Foreign Application Priority Data
Jul. 30, 2024 (KR) 10-2024-0100757

(51) Int. Cl. G11C 29/08

(52) U.S. Cl. CPC G11C 29/08

(57) ABSTRACT

A memory fault diagnosis device, a System on a Chip (SoC), and a Bloom filter update method and a memory accessibility determination method can operate to diagnose memory faults in a minimum time by using a Bloom filter to detect failed memory areas and thereby determine memory accessibility in a minimum time.

### CROSS-REFERENCE TO RELATED APPLICATION

This application claims priority under 35 U.S.C. § 119 to Korean Patent Application No. 10-2024-0100757 filed on Jul. 30, 2024, which is incorporated herein by reference in its entirety.

### BACKGROUND

### 1. Field

Illustrative embodiments relate to a System-On-a-Chip (SoC), and to a memory fault diagnosis device, a SoC, a Bloom filter update method, and a memory accessibility determination method that can diagnose memory faults in a minimum time by using a Bloom filter and determine memory accessibility in a minimum time.

### 2. Discussion of the Related Art

Because a system on chip (SoC) is a chip in which components including a Central Processing Unit (CPU), a memory, and functional blocks for performing various functions are integrated and implemented in a single chip which can reduce the size of a product and minimize power consumption, an SoC can be applied to fields of artificial intelligence, the Internet of Things, and autonomous vehicles.

In the related art wherein a CPU and a memory implemented in separate chips are used, when the CPU writes information to a memory chip or reads information written in the memory chip, when there is a defect in the memory chip, the problem has been solved by replacing the memory chip. However, because the SoC has a CPU and a memory implemented in a single chip, even though a defect occurs only in the memory area, there is a disadvantage in that the entire SoC needs to be replaced.

In a process of manufacturing SoC chips, the electrical characteristics of the SoC chip are tested. In particular, information on a memory cell where an operation defect (hereinafter, referred to as a fail) has occurred in a memory area is determined in advance, and when the CPU intends to utilize a memory, the memory cell where a fail has occurred is excluded from being used in a signal processing process.

Even when the finished product of the SoC chip is applied to an actual application product, the electrical characteristics of the SoC are tested, and among a plurality of memory cells included in the memory area of the SoC, the CPU may ascertain an additional memory cell where a fail has occurred and prevent the failed memory cell from being used in a signal processing process.

In the following description, a test performed during a manufacturing process of a SoC is referred to as a test during manufacturing and a test performed while a finished SoC product is being used is referred to as a run time test.

FIG. 1 illustrates a configuration of an SoC.

Referring to FIG. 1, 70% to 80% of the area of the SoC is memory area, and the remaining area is constituted by a logic circuit area including a CPU. As the area occupied by the memory area in the SoC increases, an increase in the amount of memory that fail in test may be expected.

FIG. 2 illustrates an example of a test unit of a memory cell in a test during manufacturing.

Referring to FIG. 2, it can be seen that in a process of testing for fails in the memory area within the SoC, a test unit may be a single memory cell (FIG. 2A, Single cell), a single column (FIG. 2B, Single column), multiple columns (FIG. 2C, Multiple columns), a single row (FIG. 2D, Single row), multiple rows (FIG. 2E, Multiple rows), and a cluster (FIG. 2F, Cluster).

FIG. 3 is an example of a bit fail map generated as a result of a test during manufacturing.

Referring to FIG. 3, it can be seen that a bit fail map (Bit Fail Map) includes four patterns Pattern 1 to Pattern 4.

FIG. 4 illustrates a process in which a CPU accesses a memory.

Referring to FIG. 4, when the CPU accesses the memory, the memory performs a process of looking up, in advance, information of a bit fail map (not illustrated) installed in advance inside the memory and whether there is fail in a memory cell corresponding to a memory address that the CPU is trying to access, reflecting a result of comparing a memory address received from the CPU with stored bit fail information, and if necessary, transmitting corrected memory address information Fault type/Fault Address to the CPU together with failed data Failed Data.

As illustrated in FIG. 4, because information needs to be transmitted/received between the CPU and the memory, which are separated into respective chips and connected to each other via a bus or the like, it is difficult to diagnose an operation defect of a corresponding memory cell while the CPU is using the memory. In addition, because a 1:1 comparison needs to be made even when a plurality of patterns included in the bit fail map are compared with a memory cell corresponding to the received memory address, there is a disadvantage in that the comparison time is considerably long.

### SUMMARY

Various embodiments are directed to providing a Bloom filter-based memory fault diagnosis device that compresses test diagnosis data by using a Bloom filter and enables utilization of fail information during an actual operation.

Various embodiments are directed to providing a SoC including a Bloom filter-based memory fault diagnosis device that compresses test diagnosis data by using a Bloom filter and enables utilization of fail information during an actual operation.

Various embodiments are directed to providing a Bloom filter update method used in a memory fault diagnosis device.

Various embodiments are directed to providing a memory accessibility determination method.

Various embodiments are directed to providing a memory fault diagnosis device that compresses test diagnosis data by using a Bloom filter and enables utilization of fail information during an actual operation.

Technical problems to be solved in the present disclosure are not limited to the aforementioned technical problems and the other unmentioned technical problems will be clearly understood by those skilled in the art from the following description.

A memory fault diagnosis device using a Bloom filter in accordance with the present disclosure may include: a pattern adaptive Bloom filter comprising a first Bloom filter, a Bloom filter dictionary, and a second Bloom filter; and a built-in self test circuit, wherein in the test mode, the built-in self test circuit performs a test on a memory and transmits bit map update information generated by processing a detected failed memory address to the pattern adaptive Bloom filter, and updates failed information in the first Bloom filter, the Bloom filter dictionary, and the second Bloom filter by using the bit map update information, and in the normal mode, the memory fault diagnosis device looks up a memory address transmitted by a CPU in the first Bloom filter, the Bloom filter dictionary, and the second Bloom filter in response to a memory access request received from the CPU, and transmits, to the CPU, a result of testing whether fail has occurred in a memory cell corresponding to a memory address required to be accessed.

A SoC in accordance with the present disclosure may include: a CPU; a memory fault diagnosis device as described above; and a memory, wherein during a test mode, the fault diagnosis device tests a memory cell where fail has occurred among memory cells constituting the memory, and during a normal mode, the CPU tests whether fail has occurred in a memory address to be used by using the fault diagnosis device.

A Bloom filter update method in accordance with the present disclosure may include: receiving a failed memory address; generating a row strip and a column strip by encoding the failed memory address; generating a hash key of the row strip and the column strip; generating a hash value by applying the hash key of the row strip and the column strip to a hash function; specifying a bit position in a bit map by using the hash value; determining whether an applied failed memory address is an initially applied failed memory address; looking up the bit map for an element when it is determined that the applied failed memory address is not the initially applied failed memory address; determining whether all indices to be looked up are 1; and updating the bit map when it is determined that the applied failed memory address is the initially applied failed memory address and all the indices are not 1.

A memory accessibility determination method in accordance with the present disclosure may include: receiving a memory access request; generating a row strip and a column strip by encoding a memory access address; generating a hash key of the row strip and the column strip; generating a hash value by applying the hash key to a hash function; specifying a bit position in a bit map by using the hash value; determining whether the bit position is included in the Bloom filter dictionary; looking up a first Bloom filter when the bit position is included in the Bloom filter dictionary; looking up a second Bloom filter when the bit position is not included in the Bloom filter dictionary; determining whether all indices of bits looked up in the first Bloom filter and the second Bloom filter are 1; denying access to a memory cell corresponding to the memory access address by a CPU when all the indices of the bits looked up in the first Bloom filter and the second Bloom filter are 1, and succeeding access to the memory cell corresponding to the memory access address by the CPU when all the indices of the bits looked up in the first Bloom filter and the second Bloom filter are not 1.

Technical advantages to be achieved in the present disclosure are not limited to the technical advantages discussed herein, and the unmentioned technical advantages will be clearly understood by those skilled in the art from the following description.

A memory fault diagnosis device using a Bloom filter, a SoC, a Bloom filter update method, and a memory accessibility determination method in accordance with the present disclosure can diagnose memory faults in a minimum time by using a Bloom filter and thereby determine memory accessibility in a minimum time.

Effects achievable in the disclosure are not limited to the aforementioned effects and the other unmentioned effects will be clearly understood by those skilled in the art from the following description.

### BRIEF DESCRIPTION OF THE DRAWINGS

FIG. 1 illustrates the configuration of a SoC.

FIGS. 2A, 2B, 2C, 2D, 2E and 2F illustrate an example of a test unit of a memory cell in a test during manufacturing.

FIG. 3 illustrates an example of a bit fail map generated as a result of a test during manufacturing.

FIG. 4 illustrates a process in which a CPU accesses a memory.

FIG. 5 illustrates an example of a SoC including a memory fault diagnosis device in accordance with the present disclosure.

FIG. 6 illustrates an example of a Bloom filter update method in a test mode.

FIG. 7 illustrates an example of a bit map update step.

FIGS. 8A, 8B, and 8C illustrates an example of a first-stage Bloom filter and a second-stage Bloom filter.

FIG. 9 illustrates an example of a method for determining whether memory access is possible in a normal mode.

FIG. 10 illustrates a step of denying memory access as a result of looking up a first-stage Bloom filter and a second-stage Bloom filter.

FIG. 11 illustrates a step of succeeding memory access as a result of looking up a first-stage Bloom filter and a second-stage Bloom filter.

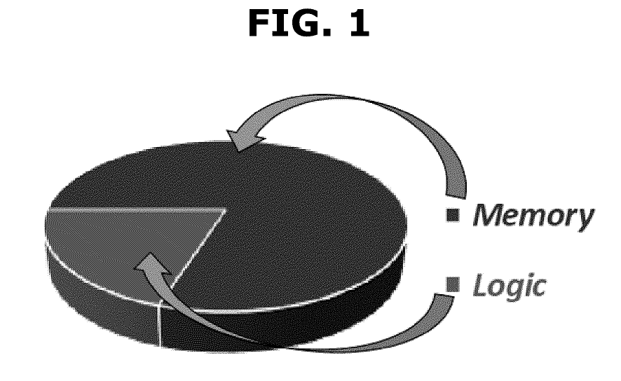

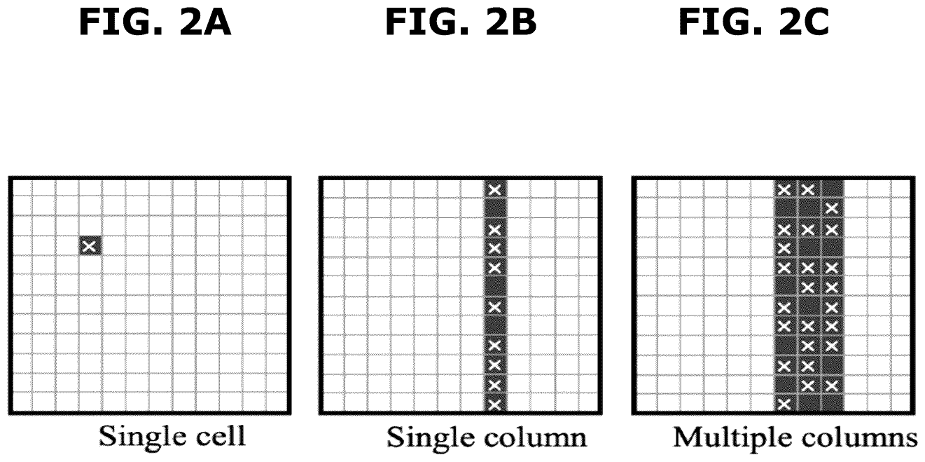

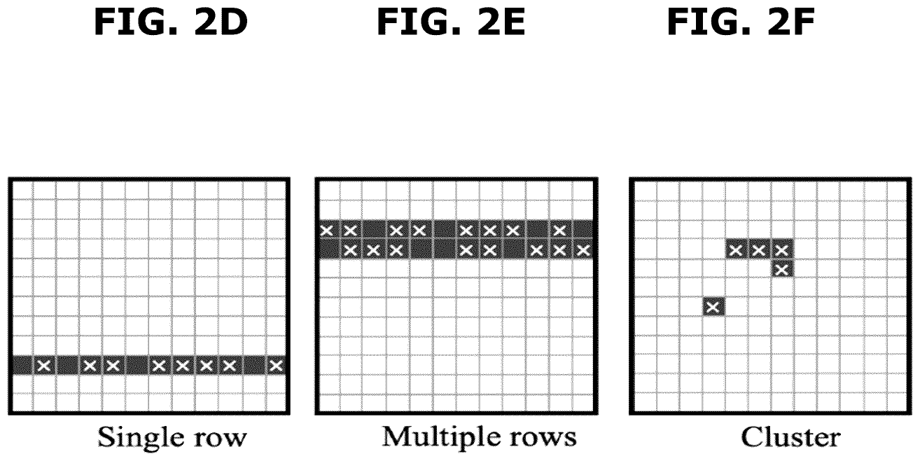

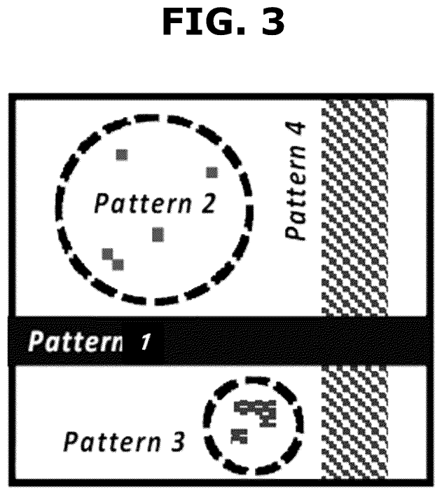

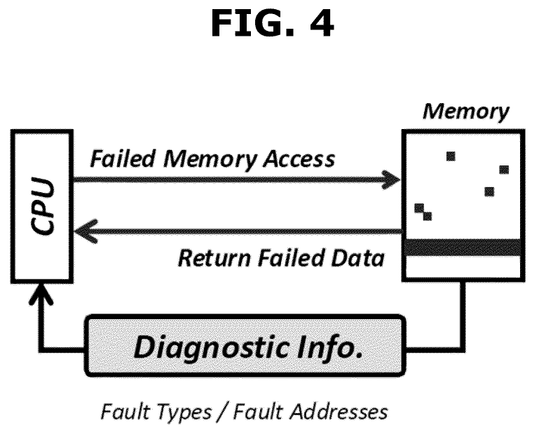

### DETAILED DESCRIPTION

In order to fully understand the present disclosure, advantages in operation of the present disclosure, and objects achieved by carrying out the present disclosure, the accompanying drawings for explaining exemplary examples of the present disclosure and the contents described with reference to the accompanying drawings need to be referred to.

Hereinafter, the present disclosure is described in detail by describing preferred embodiments of the present disclosure with reference to the accompanying drawings. The same reference numerals among the reference numerals in each drawing indicate the same members.

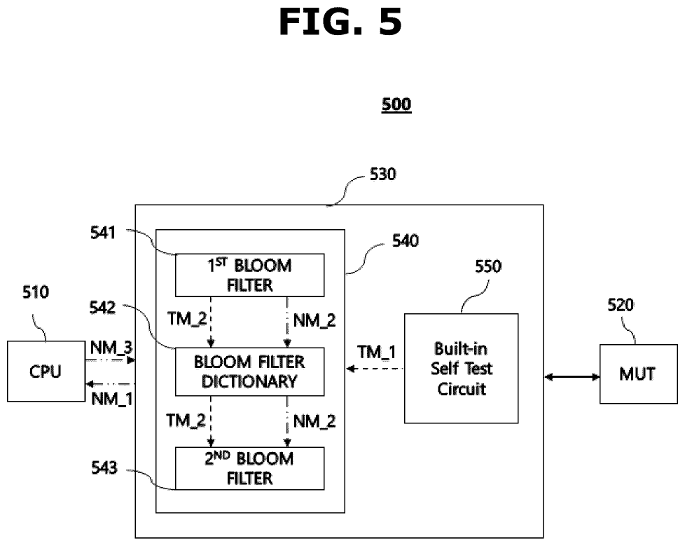

FIG. 5 illustrates an example of a SoC including a memory fault diagnosis device in accordance with the present disclosure.

Referring to FIG. 5, a SoC 500 includes a CPU 510, a memory 520 (Memory Under Test: MUT), and a memory fault diagnosis device 530.

The memory fault diagnosis device 530 in accordance with the present disclosure is installed between the CPU 510 and the memory 520 to be tested, and includes a pattern adaptive Bloom filter 540 and a built-in self test circuit 550.

The pattern adaptive Bloom filter 540 includes a first Bloom filter 541 (1^{ST} Bloom Filter), a Bloom filter dictionary 542 (Bloom Filter Dictionary), and a second Bloom filter 543 (2^{ND} Bloom Filter).

The SoC 500 may operate in a test mode (TM) and a normal mode (NM). During the test mode TM, when the memory 520 is not otherwise being used by the CPU 510, the CPU 510 tests for a memory cell in which a fail has occurred among memory cells constituting the memory 520, and during the normal mode NM, the CPU 510 performs operations by using the memory 520.

The test mode TM may be performed, for example, using the memory fault diagnosis device 530.

In the test mode TM, the built-in self test circuit 550 performs a test on the memory 520 and transmits bit map update information TM_1, generated by processing a detected failed memory address, to the pattern adaptive Bloom filter 540. The pattern adaptive Bloom filter 540 updates (TM_2) failed information in the 1^{ST} Bloom filter 541, the Bloom filter dictionary 542, and the 2^{ND} Bloom filter 543 formed therein by using the received bit map update information TM_1. The built-in self test circuit 550 may include a memory test pattern generation unit (not illustrated) that generates a plurality of patterns, data, addresses, and control signals used for testing the memory, and a signal processing unit (not illustrated) that generates the bit map update information TM_1 by processing the failed memory address.

The normal mode NM may be performed between the CPU 510 and the memory fault diagnosis device 530.

The CPU 510 transmits a memory access request (Memory Access Request: NM_1) to the memory fault diagnosis device 530, and the memory fault diagnosis device 530 performs a look up using the 1^{ST} Bloom filter 541, the Bloom filter dictionary 542, and the 2^{ND} Bloom filter 543 constituting the adaptive Bloom filter 540 in response to the memory access request NM_1 and transmits, to the CPU 510, a result NM_3 of testing whether fail has occurred in a memory cell requested to be accessed.

For convenience of description, the reference numeral 550 is named a built-in self test circuit; however, depending on the embodiment, the reference numeral 550 can be implemented with various functional blocks including a logic circuit.

In the present disclosure, diagnostic data used to test whether fail has occurred in a memory cell by using a Bloom filter is compressed using the Bloom filter, so that defects in a memory within the SoC can be quickly tested and responded to during the manufacturing of the SoC as well as during a run time test, that is, even while the SoC in the finished product state is actually being used.

In order to facilitate the understanding of the present disclosure, the general functions and characteristics of the Bloom filter are described below.

The Bloom filter is a probabilistic data structure used to test whether an element belongs to a group, and can be referred to as a device that allows unnecessary tasks to be skipped by adding the Bloom filter to tasks that may cause performance degradation.

The Bloom filter has the characteristics that a false positive fp, which represents that it has been determined by a Bloom filter that a certain element belongs to a group but the element does not actually belong to the group, may occur, but a false negative fn, which represents that it has been determined by the Bloom filter that a certain element does not belong to a group but the element actually belongs to the group, absolutely does not occur. Adding an element to a group is possible, but deleting an element from a group is not possible, and as the number of elements in a group increases, the probability of the false positive fp also increases.

When the Bloom filter is used, resultant values obtained by applying a certain value to a plurality of hash functions are indexed into an arbitrary table, and whether all values that are looked up are 1 (one) is checked.

The Bloom filter is constituted by a bit map and a hash function. The bit map may be a predefined bit string in which a plurality of memory cells are arrayed and may be included in the memory 520 to be tested. Applying an input access address to the hash function may be performed by various processors, for example, the built-in self test circuit 550.

The present disclosure proposes to convert a memory address where fail has occurred by a memory test into a row strip and a column strip for use. This reflects an experience that the position of a memory cell where fail occurs is likely to be included in a row strip or a column strip including a memory cell where fail has previously occurred. Each of the row strip and the column strip includes at least one strip in a row direction and at least one strip in a column direction.

Assuming that a Bloom filter uses a bit map including N (N is a natural number) bits and M (M is a natural number) hash functions, the number of bit maps is generally larger than the number of hash functions (N>M). 1 (one) is set to M bit positions specified in N bit maps. For example, when N is 10 and M is 3, the array index of three bit positions specified by the hash function among 10 bit strings is to be changed to 1.

The present disclosure proposes to use the Bloom filter in the manner described below.

The Bloom filter is updated in the test mode, and it has already been described above that the test mode may be performed not only during the manufacturing of the SoC, but also during a run time test, that is, when the CPU is not otherwise using the memory.

The following describes a Bloom filter update process in the test mode.

In the case of an initial test, all bits of the bit map constituting the Bloom filter are written with an index 0 (zero), and in the case of an additional test, whether to update the bit map is to be determined depending on an element to be applied.

The element is, for example, a failed memory address FMA in the case of a test process, and a memory access address Memory Access Address when in operation.

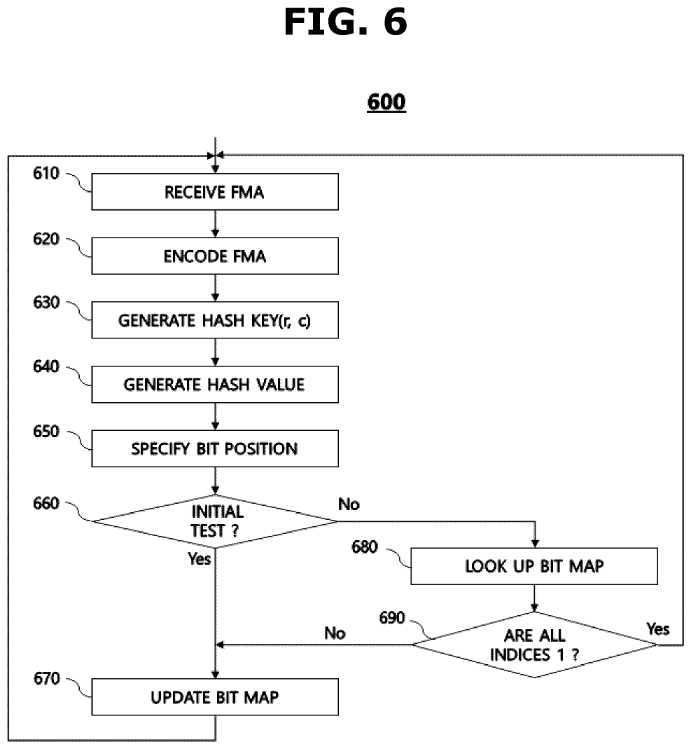

FIG. 6 illustrates an example of the Bloom filter update method in the test mode.

Since a Bloom filter update method 600 illustrated in FIG. 6 is performed by the built-in self test circuit 550 to update the bit map constituting the Bloom filter inside the pattern adaptive Bloom filter 540 by performing steps to be described below, it can be said that the Bloom filter update method 600 is performed by the memory fault diagnosis device 530.

Referring to FIG. 6, the Bloom filter update method 600 includes a step 610 of receiving a failed memory address FMA, a step 620 of generating a row strip and a column strip by encoding the received failed memory address FMA, a step 630 of generating a hash key (r, c) of the row strip and the column strip, a step 640 of generating a plurality of hash values by applying the hash key (r, c) of the row strip and the column strip to a plurality of respective hash functions, a step 650 of specifying a plurality of bit positions in a bit map by using the plurality of hash values, a step 660 of determining whether an applied failed memory address FMA is an initially applied failed memory address FMA, a step 680 of looking up the bit map for an element when it is determined that the failed memory address FMA is not the initially applied failed memory address FMA (No in 660), a step 690 of determining whether all of the plurality of bit positions to be looked up are 1 (one), and a step 670 of updating the bit map when it is determined that the failed memory address FMA is the initially applied failed memory address FMA (Yes in 660) and the plurality of bit positions are not all 1 (No in 690). When all the plurality of bit positions are determined to be 1 (Yes in 690) and after performing step 670 of updating the bit map, the step 610 of receiving another failed memory address FMA may be performed.

The failed memory address FMA may be generated by the built-in self test circuit 550 by performing a memory test, or may be generated by a separate functional block (not illustrated) having performed a memory test and transmitted by the built-in self test circuit 550.

During the update process of the Bloom filter illustrated in FIG. 6, the update is performed as follows according to the result of looking up the bit map (680).

When all bits at the plurality of position have been set to 1 (one) (Yes in 690), because this means that an additionally applied failed memory address FMA may exist in a group, it is not necessary to update the bit map. On the other hand, when any one of the N bits has been set to 0 (zero) (No in 690), because this means that the additionally applied failed memory address FMA does not exist in the group, it is necessary to update (670) the bit map for the additionally applied failed memory address FMA.

In order to reduce the rate of the false positives fp which is one of the characteristics of the Bloom filter, the present disclosure proposes to use the two-stage Bloom filters 541 and 543. Accordingly, the bit map update step 670 illustrated in FIG. 6 may have two examples as described below. The first-stage Bloom filter 541 uses a two-dimensional bit map and the second-stage Bloom filter 543 uses a one-dimensional bit map.

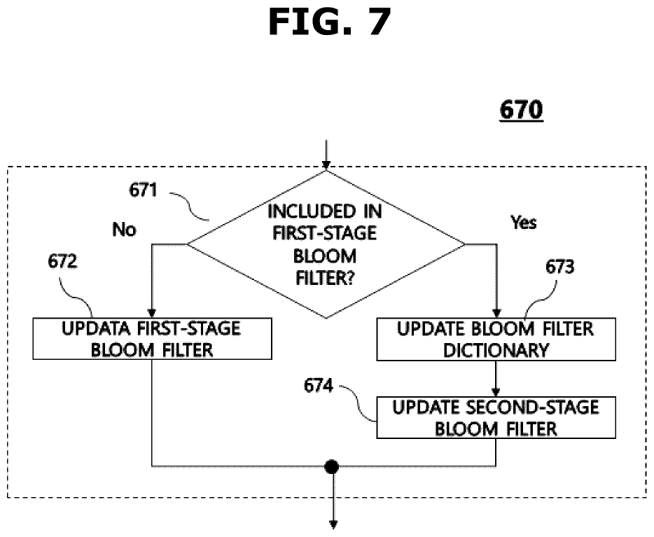

FIG. 7 illustrates an example of the bit map update step.

Referring to FIG. 7, in order to process a new failed memory address FMA that is applied as a result of a subsequent test after the first-stage Bloom filter 541 is generated, the previously generated first-stage Bloom filter 541 is looked up (671). When it is determined (No in 671) that the position of a memory cell corresponding to the new failed memory address FMA has already been determined to be fail and is not included in the first-stage Bloom filter 541, the first-stage Bloom filter 541 may be updated (672) by setting a bit position corresponding to the new failed memory address FMA to 1 to the first-stage Bloom filter 541.

As a result of looking up, in the first-stage Bloom filter 541, the new failed memory address FMA that is applied as a result of the subsequent test after the first-stage Bloom filter 541 is generated, when it is determined (Yes in 671) that the position of the memory cell corresponding to the new failed memory address FMA has already been determined to be fail and is included in the first-stage Bloom filter 541, a key value key and a row direction or a column direction being a generation direction are recorded in the Bloom filter dictionary 542 (673), and then an index corresponding to the failed memory address FMA is stored (674) in the second-stage Bloom filter 543 having the form of a one-dimensional bit map.

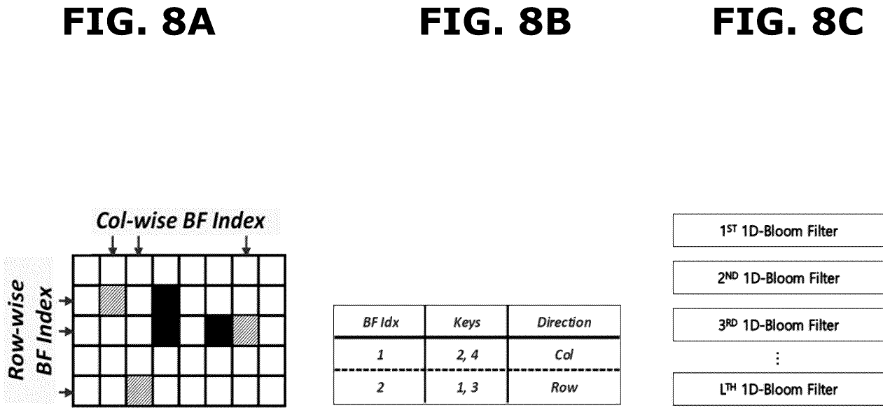

FIG. 8 illustrates an example of the first-stage Bloom filter and the second-stage Bloom filter.

FIG. 8A illustrates the first-stage Bloom filter 541 having the form of a two-dimensional bit map, FIG. 8B illustrates the Bloom filter dictionary 542, and FIG. 8C illustrates the second-stage Bloom filter 543 having the form of a one-dimensional bit map.

Referring to FIG. 8A, the first-stage Bloom filter 541 has the form of a two-dimensional bit map that may display a Bloom filter index in the column direction and a Bloom filter index in the row direction. As described above, an index 1 is written to a corresponding bit position in the two-dimensional bit map specified using a hash value, and in FIG. 8A, bits filled with black and diagonal lines correspond to this. For example, the bit filled with black may be understood as corresponding to a bit determined to have fail occurred in a test of a previous stage, and the bit filled with diagonal lines may be understood as a bit determined to have fail additionally occurred in a test of a subsequent stage.

It can be seen that the Bloom filter dictionary 542 illustrated in FIG. 8B stores information on a Bloom filter index BF Idx, a hash key Keys, and a direction Direction of a string that indicate the first-stage Bloom filter 541 or the second-stage Bloom filter 543.

With reference to FIGS. 6 to 8, the Bloom filter update method in the test mode and the two-stage Bloom filters 541 and 543 have been described.

The following describes a memory access method in a normal mode in which, when the CPU performs a signal processing process according to a memory access request MAR, the CPU determines whether fail has occurred in a memory cell corresponding to a memory access address MAA to be used by the CPU and determines whether to use the memory cell corresponding to the memory access address MAA. The main processing steps of the memory access method in the normal mode to be described below may be performed by various functional blocks, and for example, may be performed by the built-in self test circuit 550.

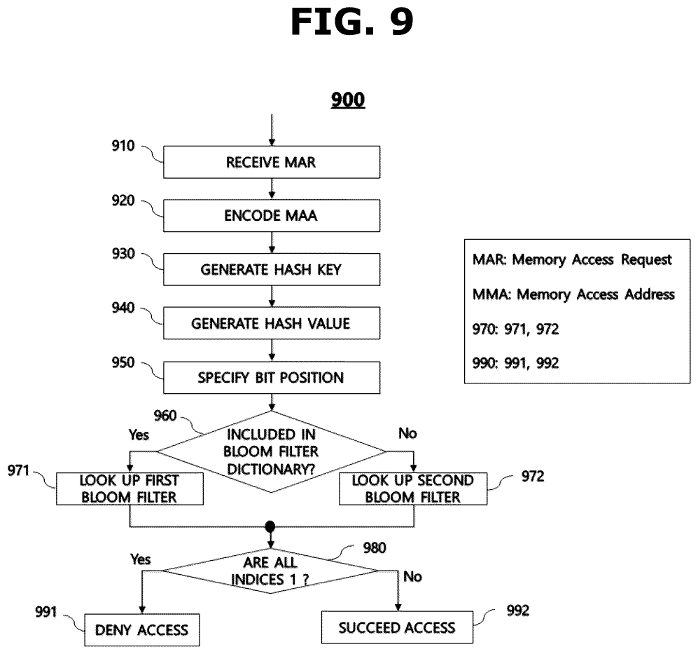

FIG. 9 illustrates an example of a method for determining whether memory access is possible in the normal mode.

Referring to FIG. 9, a method 900 for determining whether memory access is possible in accordance with the present disclosure includes a step 910 of receiving a memory access request MAR, a step 920 of generating a row strip and a column strip (Row Strip/Column Strip) by encoding a memory access address MAA, a step 930 of generating a hash key (r, c) of the row strip and the column strip, a step 940 of generating a plurality of hash values by applying the hash key (r, c) of the row strip and the column strip to a plurality of respective hash functions, a step 950 of specifying a plurality of bit positions in a bit map by using the hash values, respectively, a step 960 of determining whether one of the bit positions is included in the Bloom filter dictionary, a step 971 of looking up the first Bloom filter when one of the bit positions is included in the Bloom filter dictionary (Yes in 960), a step 972 of looking up the second Bloom filter when none of the bit position are included in the Bloom filter dictionary (No in 960), a step 980 of determining whether all indices of bits looked up in the first Bloom filter or the second Bloom filter are 1, a step 991 of denying access to a memory cell corresponding to the memory access address MAA by the CPU when all the indices of the bits looked up in the first Bloom filter and the second Bloom filter are 1 (Yes in 980), and a step 992 of succeeding access to the memory cell corresponding to the memory access address MAA by the CPU when not all of the indices of the bits looked up in the first Bloom filter or the second Bloom filter are 1 (No in 980).

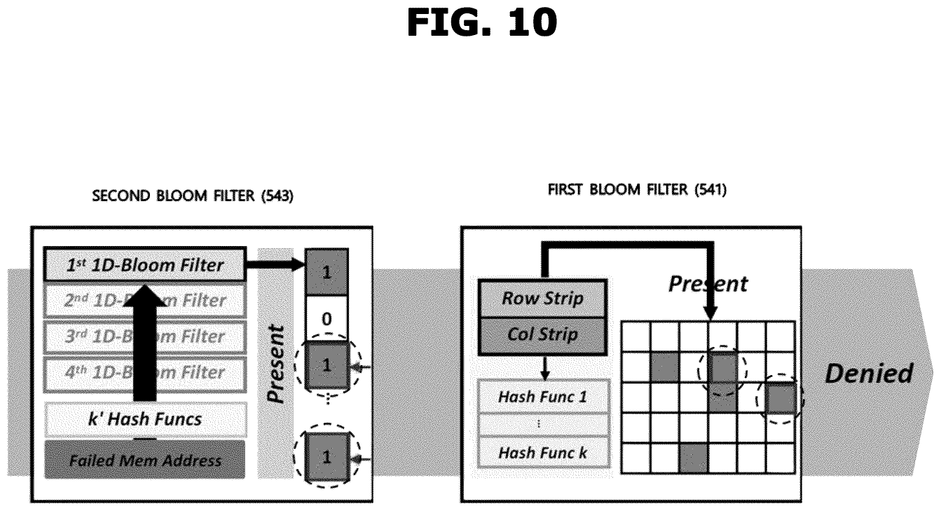

FIG. 10 illustrates the step of denying memory access as a result of looking up the first-stage Bloom filter and the second-stage Bloom filter.

Referring to FIG. 10, because the indices of two positions (dotted circles) of two bit maps constituting the two Bloom filters 541 and 543 corresponding to two bits to be looked up are also 1 (one), the memory access is denied.

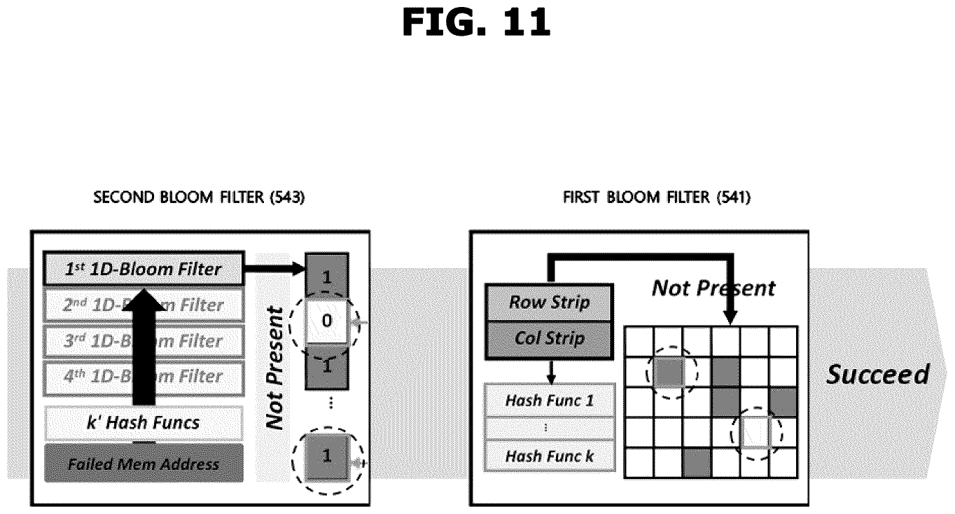

FIG. 11 illustrates the step of succeeding memory access as a result of looking up the first-stage Bloom filter and the second-stage Bloom filter.

Referring to FIG. 11, because one of the indices of two positions (dotted circles) of the two bit maps constituting the two Bloom filters corresponding to the two bits to be looked up is not 1 but 0 (zero), the memory access succeeds.

Although the technical spirit of the present disclosure has been described together with the accompanying drawings, this is an illustrative example of a preferred embodiment of the present disclosure, but does not limit the present disclosure. In addition, it is clear that various modifications and imitations can be made by anyone skilled in the art to which the present disclosure belongs without departing from the scope of the technical spirit of the present disclosure.

What is claimed is:

1. A memory fault diagnosis device that operates in a test mode and a normal mode, comprising:
a pattern adaptive Bloom filter comprising a first Bloom filter, a Bloom filter dictionary, and a second Bloom filter; and
a built-in self test circuit,
wherein in the test mode, the built-in self test circuit performs a test on a memory and transmits bit map update information generated by processing a detected failed memory address to the pattern adaptive Bloom filter, and updates failed information in the first Bloom filter, the Bloom filter dictionary, and the second Bloom filter by using the bit map update information, and
in the normal mode, the memory fault diagnosis device looks up a memory address transmitted by a CPU in the Bloom filter dictionary and in one or more of the first Bloom Filter and the second Bloom filter in response to a memory access request received from the CPU, and transmits, to the CPU, a result of testing whether fail has occurred in a memory cell corresponding to a memory address required to be accessed.

2. The memory fault diagnosis device of claim 1, wherein the built-in self test circuit comprises:
a memory test pattern generation unit configured to generate a plurality of patterns, data, an address, and a control signal used for testing the memory; and
a signal processing unit configured to generate the bit map update information by processing the failed memory address.

3. The memory fault diagnosis device of claim 1, wherein the first Bloom filter comprises a two-dimensional bit map that is able to display a Bloom filter index in a column direction and the Bloom filter index in a row direction,
the second Bloom filter comprises a one-dimensional bit map, and
the Bloom filter dictionary comprises information on the Bloom filter index, a hash key, and a direction of a string that indicate the first-stage Bloom filter or the second-stage Bloom filter.

4. A SoC comprising:
a CPU;
a memory fault diagnosis device of claim 3; and
a memory,
wherein during a test mode, the fault diagnosis device tests a memory cell where fail has occurred among memory cells constituting the memory, and
during a normal mode, the CPU tests whether fail has occurred in a memory address to be used by using the fault diagnosis device.

5. A Bloom filter update method comprising:
receiving a failed memory address;
generating a row strip and a column strip by encoding the failed memory address;
generating a hash key of the row strip and the column strip;
generating a plurality of hash values by applying the hash key of the row strip and the column strip to a plurality of hash functions;
specifying a plurality of bit positions in a bit map by using the plurality of hash values respectively;
determining whether an applied failed memory address is an initially applied failed memory address;
looking up the bit map for an element using the plurality of bit positions as indices when it is determined that the applied failed memory address is not the initially applied failed memory address;
determining whether all the indices to be looked up are 1; and
updating the bit map when it is determined that the applied failed memory address is the initially applied failed memory address and not all the indices are 1.

6. The Bloom filter update method of claim 5, wherein the Bloom filter update method is performed by the built-in self test circuit of claim 3.

7. The Bloom filter update method of claim 6, wherein the updating of the bit map comprises:
looking up the first Bloom filter in order to process a new failed memory address that is applied as a result of a subsequent test after the first Bloom filter is generated;
setting a bit position corresponding to the new failed memory address to 1 in the first Bloom filter when it is determined that a position of a memory cell corresponding to the new failed memory address has already been determined to be fail and is not included in the first Bloom filter;
recording, in a Bloom filter dictionary, a key value key and a row direction or a column direction being a generation direction when it is determined that the position of the memory cell corresponding to the new failed memory address has already been determined to be fail and is included in the first Bloom filter; and
updating an index corresponding to the failed memory address in the second Bloom filter.

8. The Bloom filter update method of claim 5, wherein the receiving of the failed memory address is performed when all indices that are looked up are determined to be 1 and after performing the updating of the bit map.

9. The Bloom filter update method of claim 6, wherein the failed memory address is generated by the built-in self test circuit by performing a test on a memory to be tested, or is received by the built-in self test circuit from a separate functional block having performed a memory test.

10. A memory accessibility determination method comprising:
receiving a memory access request;
generating a row strip and a column strip by encoding a memory access address;
generating a hash key of the row strip and the column strip;
generating a plurality of hash values by applying the hash key to a plurality of hash functions, respectively;
specifying a plurality of bit positions in a bit map by using the plurality of hash values, respectively;
determining whether a bit position of the bit positions is included in the Bloom filter dictionary;
looking up, using the plurality of hash values, a first Bloom filter to produce a plurality of indices of bits when the bit position is included in the Bloom filter dictionary;
looking up, using the plurality of hash values, a second Bloom filter to produce the plurality of indices of the bits when the bit position is not included in the Bloom filter dictionary;
determining whether all the indices of the bits are 1;
denying access to a memory cell corresponding to the memory access address by a CPU when all the indices of the bits are 1, and
succeeding access to the memory cell corresponding to the memory access address by the CPU when not all the indices of the bits are 1.

11. The memory accessibility determination method of claim 10, wherein the memory accessibility determination method is performed by the SoC of claim 4.
